(19) United States
(12) Patent Application Publication
(10) Pub. No.: US 2026/0020300 A1
(43) Pub. Date: Jan. 15, 2026

(54) SEMICONDUCTOR DEVICE AND METHOD FOR MANUFACTURING SEMICONDUCTOR DEVICE

(71) Applicant: Nuvoton Technology Corporation Japan, Kyoto (JP)

(72) Inventor: Yusuke KANDA, Toyama (JP)

(21) Appl. No.: 19/333,056

(22) Filed: Sep. 18, 2025

Related U.S. Application Data
(63) Continuation of application No. PCT/JP2024/012641, filed on Mar. 28, 2024.
(60) Provisional application No. 63/493,030, filed on Mar. 30, 2023.

(51) Int. Cl. H10D 62/10; H10D 30/01; H10D 30/47; H10D 64/60

(52) U.S. Cl. CPC H10D 62/117; H10D 30/015; H10D 30/475; H10D 64/60

(57) ABSTRACT

A semiconductor device includes: an electron transport layer; an electron supply layer provided above the electron transport layer; a gate electrode provided above the electron supply layer; a contact layer embedded in penetrating recessed portions that penetrate through the electron supply layer, at positions between which the gate electrode is provided; an electron-supply assisting layer that is an example of an n-type semiconductor layer provided in contact with the electron supply layer and the contact layer and not in contact with the gate electrode, the n-type semiconductor layer being made of an n-type semiconductor containing Si; an alloy layer provided above the electron-supply assisting layer and containing Si; a first insulating layer provided in contact with the gate electrode and not in contact with the contact layer; and at least one of a source electrode or a drain electrode provided above the alloy layer and the contact layer.

### CROSS REFERENCE TO RELATED APPLICATIONS

This is a continuation application of PCT International Patent Application No. PCT/JP2024/012641 filed on Mar. 28, 2024, designating the United States of America, which is based on and claims priority of U.S. Provisional Patent Application No. 63/493,030 filed on Mar. 30, 2023. The entire disclosures of the above-identified applications, including the specifications, drawings and claims are incorporated herein by reference in their entirety.

### FIELD

The present disclosure relates to a semiconductor device and a method for manufacturing the same, and in particular to a group III nitride semiconductor device that includes a group III nitride semiconductor and a method for manufacturing the same.

### BACKGROUND

A group III nitride semiconductor device that includes a group III nitride semiconductor or in particular, gallium nitride (GaN) or aluminum gallium nitride (AlGaN) has a high breakdown voltage since its material has a wide band gap. In the group III nitride semiconductor device, a heterostructure of AlGaN and GaN, for instance, can be readily formed.

In an AlGaN/GaN heterostructure, highly concentrated electrons (a two-dimensional electron gas) are generated on a GaN layer side of an interface between an AlGaN layer and a GaN layer so that a channel of a two-dimensional electron gas layer is formed, because of a difference between piezo polarization caused by a difference in lattice constant between the materials and spontaneous polarization of AlGaN and GaN. A group III nitride semiconductor device that utilizes a channel of such a two-dimensional electron gas has a relatively high electron saturation velocity, relatively high insulation resistance, and a relatively high thermal conductivity, and thus is applied to high-frequency power devices, for instance.

In order to enhance properties of such a group III nitride semiconductor device, a contact between an ohmic electrode and the two-dimensional electron gas layer inside the group III nitride semiconductor device (hereinafter, referred to as “ohmic contact”) and a parasitic resistance component such as a resistance of a channel made by a two-dimensional electron gas may be reduced as much as possible.

Conventionally, a technique of reducing an ohmic contact resistance in a group III nitride semiconductor device that utilizes a channel made by a two-dimensional electron gas has been proposed. For example, Patent Literature (PTL) 1 has disclosed a technique of forming a recessed portion that penetrates through an electron supply layer made of AlGaN (hereinafter, referred to as a “penetrating recessed portion”) in a portion in which an ohmic electrode is to be formed inside the group III nitride semiconductor device to form an ohmic electrode, in order to reduce an ohmic contact resistance.

### CITATION LIST

### Patent Literature

PTL 1: International Publication No. WO2021/246227

### SUMMARY

### Technical Problem

However, if a penetrating recessed portion is formed in an electron supply layer as shown by the technique disclosed by PTL 1, a two-dimensional electron gas layer and a contact layer embedded in the penetrating recessed portion are essentially connected by points, which is inevitable. Furthermore, if a penetrating recessed portion is formed in the electron supply layer, not only crystal defects are caused at an interface between the contact layer and a two-dimensional electron gas layer (a channel layer) made of GaN when the penetrating recessed portion is formed, but also a region in which a carrier (electron) concentration lowers is generated at the interface in a portion of an electron supply layer adjacent to the lateral surface of the penetrating recessed portion due to pollutants in the atmosphere and a bond defect so that the maximum drain current decreases, which is a problem.

The present disclosure has been conceived in view of such a problem, and provides a semiconductor device that can reduce a decrease in the maximum drain current and a method for manufacturing the same.

### Solution to Problem

In order to provide such a semiconductor device, a semiconductor device according to an aspect of the present disclosure includes: an electron transport layer; an electron supply layer provided above the electron transport layer and having a band gap greater than a band gap of the electron transport layer; a gate electrode provided above the electron supply layer; a source-side contact layer and a drain-side contact layer that are embedded in recessed portions that penetrate through the electron supply layer, at positions between which the gate electrode is provided; an n-type semiconductor layer provided in contact with the electron supply layer and at least one of the source-side contact layer or the drain-side contact layer and not in contact with the gate electrode, the n-type semiconductor layer being made of an n-type semiconductor containing Si; an alloy layer provided above the n-type semiconductor layer, containing Si, and having a thickness of at most 2 nm; an insulating layer provided above a portion of the electron supply layer in which the gate electrode is not provided, in contact with the gate electrode, and not in contact with at least one of the source-side contact layer or the drain-side contact layer; and at least one of a source electrode or a drain electrode provided above the alloy layer and at least one of the source-side contact layer or the drain-side contact layer.

A first method for manufacturing a semiconductor device according to an aspect of the present disclosure includes: forming an electron supply layer above an electron transport layer, the electron supply layer having a band gap greater than a band gap of the electron transport layer; forming an insulating layer containing Si above the electron supply layer without exposure to atmosphere; forming a thin portion in the insulating layer by thinning a portion of the insulating layer; forming a penetrating recessed portion that penetrates through the thin portion of the insulating layer and the electron supply layer and reaches up to the electron transport layer while retaining a portion of the thin portion as an insulating-layer remaining portion; embedding a contact layer in the penetrating recessed portion; forming at least one of a source electrode or a drain electrode over the insulating-layer remaining portion and the contact layer; forming an alloy layer and an electron-supply assisting layer in the insulating-layer remaining portion and the electron supply layer by applying a heat treatment; and removing a portion of the insulating layer that is separated from the at least one of the source electrode or the drain electrode to form a gate electrode.

A second method for manufacturing a semiconductor device according to an aspect of the present disclosure includes: forming an electron supply layer above an electron transport layer, the electron supply layer having a band gap greater than a band gap of the electron transport layer; forming an insulating layer containing Si above the electron supply layer without exposure to atmosphere; forming a thin portion in the insulating layer by thinning a portion of the insulating layer; forming a penetrating recessed portion that penetrates through the thin portion of the insulating layer and the electron supply layer and reaches up to the electron transport layer while retaining a portion of the thin portion as an insulating-layer remaining portion; forming at least one of a source electrode or a drain electrode over the insulating-layer remaining portion and the penetrating recessed portion; forming an alloy layer and an electron-supply assisting layer in the insulating-layer remaining portion and the electron supply layer by applying a heat treatment; and removing a portion of the insulating layer that is separated from the at least one of the source electrode or the drain electrode to form a gate electrode.

### Advantageous Effects

According to the present disclosure, a semiconductor device that can reduce a decrease in the maximum drain current can be obtained.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view illustrating a configuration of a semiconductor device according to Embodiment 1.

FIG. 2 is a schematic diagram illustrating a conduction band of an energy band of the semiconductor device according to Embodiment 1.

FIG. 3A is a cross-sectional view illustrating a process of forming a semiconductor layered structure, a first insulating layer, and a second insulating layer in a method for manufacturing the semiconductor device according to Embodiment 1.

FIG. 3B is a cross-sectional view illustrating a process of forming thin portions in the first insulating layer in the method for manufacturing the semiconductor device according to Embodiment 1.

FIG. 3C is a cross-sectional view illustrating a process of forming penetrating recessed portions in the method for manufacturing the semiconductor device according to Embodiment 1.

FIG. 3D is a cross-sectional view illustrating a process of forming a contact layer in the method for manufacturing the semiconductor device according to Embodiment 1.

FIG. 3E is a cross-sectional view illustrating a process of forming a source electrode and a drain electrode in the method for manufacturing the semiconductor device according to Embodiment 1.

FIG. 3F is a cross-sectional view illustrating a process of applying a heat treatment in the method for manufacturing the semiconductor device according to Embodiment 1.

FIG. 3G is a cross-sectional view illustrating a process of forming a gate electrode in the method for manufacturing the semiconductor device according to Embodiment 1.

FIG. 4 is a cross-sectional view illustrating a configuration of a semiconductor device according to Embodiment 2.

FIG. 5A is a cross-sectional view illustrating a process of forming a semiconductor layered structure, a first insulating layer, and a second insulating layer in a method for manufacturing the semiconductor device according to Embodiment 2.

FIG. 5B is a cross-sectional view illustrating a process of forming thin portions in the first insulating layer in the method for manufacturing the semiconductor device according to Embodiment 2.

FIG. 5C is a cross-sectional view illustrating a process of forming penetrating recessed portions in the method for manufacturing the semiconductor device according to Embodiment 2.

FIG. 5D is a cross-sectional view illustrating a process of forming a source electrode and a drain electrode in the method for manufacturing the semiconductor device according to Embodiment 2.

FIG. 5E is a cross-sectional view illustrating a process of applying a heat treatment in the method for manufacturing the semiconductor device according to Embodiment 2.

FIG. 5F is a cross-sectional view illustrating a process of forming a gate electrode in the method for manufacturing the semiconductor device according to Embodiment 2.

### DESCRIPTION OF EMBODIMENTS

In the following, embodiments of the present disclosure are described with reference to the drawings. The embodiments shown herein show specific examples of the present disclosure. Thus, the numerical values, shapes, elements, the arrangement and connection of the elements, steps (processes), and the order of processing the steps, for instance, described in the following embodiments are examples, and thus are not intended to limit the present disclosure. Among the elements in the following embodiments, elements not recited in any of the independent claims defining the most generic concept of the present disclosure are described as optional elements.

The drawings are schematic diagrams, and do not necessarily provide strictly accurate illustration. Accordingly, scales, for instance, are not necessarily the same in the drawings. In the drawings, the same sign is given to substantially the same configuration, and a redundant description thereof is omitted or simplified.

In this specification, the terms “above”, “upward”, “below”, and “downward” in the configuration of a semiconductor device do not indicate upward (vertically upward) or downward (vertically downward) in the absolute recognition of space, but are terms defined by a relative positional relation based on the stacking order in a layered structure. Furthermore, the terms “above” and “below” are used not only when two elements are spaced apart from each other and another element is present therebetween, but also when two elements are disposed in close contact with each other so that the two elements are touching each other.

In the specification and the drawings, the x axis, the y axis, and the z axis represent three axes of a three-dimensional orthogonal coordinate system. In the embodiments, the two axes parallel to the upper surface of a substrate included in a semiconductor device are the x axis and the y axis, and the direction orthogonal to this upper surface is the z-axis direction. In the embodiments described below, the z-axis positive direction may be stated as upward and the z-axis negative direction may be stated as downward. Note that in the specification, a “plan view” refers to a state when the substrate included in the semiconductor device is viewed in the z-axis positive direction.

### Embodiment 1

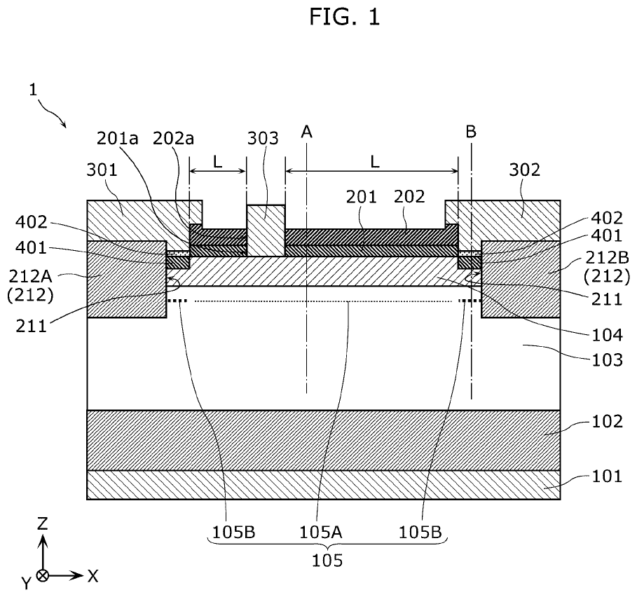

First, semiconductor device 1 according to Embodiment 1 is described with reference to FIG. 1. FIG. 1 is a cross-sectional view illustrating a configuration of semiconductor device 1 according to Embodiment 1.

In the present embodiment, the case in which semiconductor device 1 is a high electron mobility transistor (HEMT) that includes a Schottky junction gate structure is described.

As illustrated in FIG. 1, semiconductor device 1 includes substrate 101, buffer layer 102, electron transport layer 103, electron supply layer 104, first insulating layer 201, second insulating layer 202, source electrode 301, drain electrode 302, gate electrode 303, electron-supply assisting layer 401, and alloy layer 402.

Substrate 101 is a silicon substrate made of Si, for example. In the present embodiment, substrate 101 is a silicon substrate made of a Si monocrystal having a principal surface that is the (111) plane, for example. Note that substrate 101 is not limited to a silicon substrate, but may be a substrate made of sapphire, SiC, GaN, or AlN, for instance, that is a ground for forming a nitride semiconductor layer. The resistivity of substrate 101 is at least 1 kΩ, for example. Note that a substrate whose resistivity is at most 20 Ω may be used as substrate 101.

Buffer layer 102 is provided above substrate 101. Buffer layer 102 is a group III nitride semiconductor layer having a structure of stacked AlN and AlGaN layers and having a thickness of 2 μm. In this case, an AlN layer and an AlGaN layer may form one pair, and 20 to 100 pairs of the layers may be stacked. Buffer layer 102 may have a superlattice structure in which a plurality of Al_{1-α}Ga_{α}N (0≤α<0.8) layers are stacked. Other than those, buffer layer 102 may include a single layer or multiple layers made of one or more group III nitride semiconductors such as InGaN and AlInGaN. Note that the resistance of buffer layer 102 may be increased by setting the carbon concentration of buffer layer 102 to at least 1×10¹⁹ atoms/cm³.

Electron transport layer 103 is provided above buffer layer 102. In the present embodiment, electron transport layer 103 is a GaN layer made of GaN and having a thickness of 150 nm, for example. Note that the group III nitride semiconductor included in electron transport layer 103 is not limited to GaN. Electron transport layer 103 may be made of a group III nitride semiconductor such as InGaN, AlGaN, or AlInGaN. Electron transport layer 103 may include n-type impurities.

Electron supply layer 104 is provided above electron transport layer 103. Electron supply layer 104 has a bigger band gap than the band gap of electron transport layer 103. In the present embodiment, electron supply layer 104 is an AlGaN layer made of AlGaN having the Al composition ratio of 30% and having a thickness of 13 nm, for example. A highly concentrated two-dimensional electron gas is generated on the electron transport layer 103 side of the heterointerface between electron supply layer 104 and electron transport layer 103, and a channel of two-dimensional electron gas layer 105 is formed. Thus, semiconductor device 1 has two-dimensional electron gas layer 105. Although details are described later, two-dimensional electron gas layer 105 includes first two-dimensional electron gas layer 105A and second two-dimensional electron gas layer 105B having different electron concentrations of the two-dimensional electron gas.

Note that the Al composition ratio of electron supply layer 104 made of AlGaN is not limited to 30%. The Al composition ratio of electron supply layer 104 may be in a range of 20% to 100%. Furthermore, the group III nitride semiconductor included in electron supply layer 104 is not limited to AlGaN. Electron supply layer 104 may be made of a group III nitride semiconductor that includes In, such as AlInGaN. Electron supply layer 104 may include n-type impurities.

A cap layer may be provided above electron supply layer 104. As a cap layer, a GaN layer having a thickness of about 1 nm to 2 nm and made of GaN, for example, can be used. A spacer layer may be provided between electron transport layer 103 and electron supply layer 104. An AlN layer made of AlN and having a thickness of about 1 nm, for example, can be used as the spacer layer.

First insulating layer 201 is provided above electron supply layer 104. First insulating layer 201 is an insulating layer containing Si (silicon). In the present embodiment, first insulating layer 201 is an SiN layer made of SiN. Specifically, first insulating layer 201 is an SiN layer made of in-situ SiN and having a thickness of 2 nm. Note that in-situ means being formed without exposure to the atmosphere. Thus, first insulating layer 201 made of in-situ SiN is an SiN layer formed without exposure to the atmosphere after electron supply layer 104 is formed.

By making first insulating layer 201 using in-situ SiN in this manner, maldistribution of oxygen at the interface between first insulating layer 201 and electron supply layer 104 can be eliminated. By eliminating maldistribution of oxygen at the interface between first insulating layer 201 and electron supply layer 104, the occurrence of an interface state can be reduced. Accordingly, an increase in potential at the interface can be avoided and a decrease in electron concentration of a two-dimensional electron gas can be reduced.

The thickness of first insulating layer 201 may be at least 2 nm and at most 30 nm. By setting the thickness of first insulating layer 201 to at least 2 nm, maldistribution of oxygen caused by natural oxidation at the interface between first insulating layer 201 and electron supply layer 104 can be reduced. On the other hand, if the thickness of first insulating layer 201 exceeds 30 nm, a wafer warps when semiconductor device 1 is produced, so that the quality of semiconductor device 1 decreases. Accordingly, the thickness of first insulating layer 201 may be at most 30 nm. Thus, the warping of a wafer can be reduced by setting the thickness of first insulating layer 201 to 30 nm or less.

First insulating layer 201 may not contain oxygen. If first insulating layer 201 contains oxygen, the interface state at the interface between first insulating layer 201 and electron supply layer 104 increases, and the potential at the interface between first insulating layer 201 and electron supply layer 104 increases and the electron concentration of the two-dimensional electron gas decreases. Since first insulating layer 201 does not contain oxygen, a decrease in electron concentration of the two-dimensional electron gas can be reduced.

Second insulating layer 202 is provided above first insulating layer 201. In the present embodiment, second insulating layer 202 is in contact with first insulating layer 201. The thickness of second insulating layer 202 is greater than the thickness of first insulating layer 201, but is not limited to thereto. Thus, the thickness of second insulating layer 202 may be less than the thickness of first insulating layer 201. Second insulating layer 202 is a silicon oxide layer made of SiO₂ and having a thickness of 50 nm, for example. Note that the material of second insulating layer 202 is not limited to SiO₂, but may be SiN or SiON, for instance.

Opening portion 201a is provided in first insulating layer 201. Opening portion 201a is formed in a region of first insulating layer 201 in which gate electrode 303 is to be provided. Thus, first insulating layer 201 is provided above a portion of electron supply layer 104 in which gate electrode 303 is not provided.

Opening portion 202a is provided in second insulating layer 202. Opening portion 202a is provided in a region of second insulating layer 202 in which gate electrode 303 is to be provided. Thus, second insulating layer 202 is provided above a portion of first insulating layer 201 in which gate electrode 303 is not provided.

First insulating layer 201 and second insulating layer 202 are in contact with gate electrode 303. First insulating layer 201 and second insulating layer 202 are not in contact with contact layer 212. In the present embodiment, first insulating layer 201 and second insulating layer 202 are not in contact with any of source-side contact layer 212A or drain-side contact layer 212B, but the configuration is not limited thereto. For example, first insulating layer 201 may not be in contact with one of source-side contact layer 212A or drain-side contact layer 212B, but may be in contact with the other of the two layers. Furthermore, second insulating layer 202 may not be in contact with one of source-side contact layer 212A or drain-side contact layer 212B, but may be in contact with the other of the two layers.

Penetrating recessed portions 211 are provided in electron supply layer 104. In the present embodiment, penetrating recessed portions 211 are provided, penetrating through first insulating layer 201 and electron supply layer 104 to reach electron transport layer 103. Penetrating recessed portions 211 reach up to the inner part of electron transport layer 103, and recessed portions are provided in electron transport layer 103.

The distance between the upper surface of electron transport layer 103 and the lowest bottom portion of the bottom surface of penetrating recessed portion 211 may be at most 10 nm. As an example, the distance between the upper surface of electron transport layer 103 and the lowest bottom portion of the bottom surface of penetrating recessed portion 211 is 5 nm. The angle of elevation from the center portion of the bottom surface of penetrating recessed portion 211 to the lateral portion thereof may be at most 10 degrees, or may optionally be at most 5 degrees. In this manner, the occurrence of crystal defects on the lateral surfaces of penetrating recessed portions 211 when penetrating recessed portions 211 are formed by dry etching can be reduced, and a decrease in maximum drain current can be reduced.

Penetrating recessed portions 211 are provided in correspondence with regions in which source electrode 301 and drain electrode 302 are to be provided. Specifically, a pair of penetrating recessed portions 211 are provided facing each other with gate electrode 303 being provided therebetween.

Contact layer 212 is provided in penetrating recessed portions 211. Contact layer 212 is provided being embedded in penetrating recessed portions 211. Contact layer 212 provided in one of the pair of penetrating recessed portions 211 is source-side contact layer 212A, and contact layer 212 provided in the other of the pair of penetrating recessed portions 211 is drain-side contact layer 212B. Source-side contact layer 212A and drain-side contact layer 212B are provided in positions between which gate electrode 303 is provided.

Note that penetrating recessed portions 211 are provided separately from first insulating layer 201 and second insulating layer 202. Thus, contact layer 212 embedded in penetrating recessed portions 211 is also separated from first insulating layer 201 and second insulating layer 202, and is not in contact with first insulating layer 201 or second insulating layer 202.

Contact layer 212 is an n-GaN layer made of n-type GaN, for example. Note that the material of contact layer 212 is not limited to n-type GaN, and contact layer 212 may be made of a group III nitride semiconductor such as InGaN, AlGaN, or AlInGaN and containing a donor such as Si or Ge as n-type impurities, or may be configured of a multi-layer electrode film having a layered structure in which Ti and Al layers are stacked in this order. Furthermore, contact layer 212 may be made using a material such as Ti, Ta, Al, Au, Hf, Ru, or Cu.

Source electrode 301 and drain electrode 302 are provided above contact layer 212. Specifically, source electrode 301 is provided above source-side contact layer 212A, whereas drain electrode 302 is provided above drain-side contact layer 212B. Source electrode 301 and drain electrode 302 face each other with gate electrode 303 being provided therebetween.

Source electrode 301 and drain electrode 302 are provided above contact layer 212 and alloy layer 402. In the present embodiment, source electrode 301 and drain electrode 302 each further cover a portion of second insulating layer 202. Specifically, source electrode 301 is provided covering source-side contact layer 212A, alloy layer 402, and a portion of second insulating layer 202. Drain electrode 302 is provided covering drain-side contact layer 212B, alloy layer 402, and a portion of second insulating layer 202.

Source electrode 301 and drain electrode 302 are configured of, for example, a multi-layer electrode film having a layered structure in which a Ti film having a thickness of 30 nm and an Al film having a thickness of 200 nm are stacked in this order, but are not limited to these. Source electrode 301 and drain electrode 302 may be made using at least one of Ti, Ta, W, Al, Au, Hf, Ru, or Cu.

Gate electrode 303 is provided above electron supply layer 104. Specifically, gate electrode 303 is provided above electron supply layer 104 via opening portion 201a provided in first insulating layer 201 and opening portion 202a provided in second insulating layer 202. Note that the width of opening portion 201a of first insulating layer 201 is the same as the width of opening portion 202a of second insulating layer 202, but the configuration is not limited thereto.

Gate electrode 303 is a multi-layer electrode film having a layered structure in which a TiN film and an Al film are stacked in this order, for example. Note that gate electrode 303 is not limited to a layered structure of a TiN film and an Al film, but may be made of at least one of a transition metal nitride or a transition metal carbide. Specifically, gate electrode 303 may be made of TIN, WN, TaN, or HfN. Gate electrode 303 may be made using Ti, Ta, W, Al, Pd, Pt, Hf, Ru, or Cu, may be a chemical compound that contains such an element, or may be a multi-layer electrode film having a structure of stacked layers. Note that another insulating layer or a p-type nitride semiconductor layer may be provided between electron supply layer 104 and gate electrode 303.

Electron-supply assisting layer 401 is an n-type semiconductor layer made of an n-type semiconductor containing Si. The thickness of electron-supply assisting layer 401 may be at most 2 nm, but is not limited thereto. In the present embodiment, electron-supply assisting layer 401 is an n-AlGaN layer containing Si, having a thickness of 1 nm, and made of n-type AlGaN.

Electron-supply assisting layer 401 is not in contact with gate electrode 303 and is in contact with electron supply layer 104 and contact layer 212. In a plan view, electron-supply assisting layer 401 is provided between contact layer 212 and first insulating layer 201. In a cross-sectional view, electron-supply assisting layer 401 is provided being embedded in end portions of electron supply layer 104 closer to contact layer 212. Specifically, electron-supply assisting layer 401 is provided in such a manner that the upper surface is flush with the upper surface of electron supply layer 104 and the lower surface is located between the upper surface and the lower surface of electron supply layer 104, in a cross-sectional view.

In the present embodiment, electron-supply assisting layer 401 is in contact with both source-side contact layer 212A and drain-side contact layer 212B. Specifically, electron-supply assisting layer 401 is embedded in an end portion of electron supply layer 104 closer to source-side contact layer 212A and also embedded in an end portion thereof closer to drain-side contact layer 212B. Note that electron-supply assisting layer 401 may be in contact with just one of source-side contact layer 212A or drain-side contact layer 212B. Electron-supply assisting layer 401 may be divided into a plurality of portions. In this case, among the portions of electron-supply assisting layer 401, a portion of electron-supply assisting layer 401 closer to source electrode 301 may be in contact with source-side contact layer 212A, and a portion of electron-supply assisting layer 401 closer to drain electrode 302 may be in contact with drain-side contact layer 212B.

The width of electron-supply assisting layer 401 may be smaller than distance L between an end portion of electron-supply assisting layer 401 closer to gate electrode 303 and gate electrode 303. As an example, the width of electron-supply assisting layer 401 is at most 1 μm in a cross-sectional view. By adopting such a configuration, an increase in leakage current between gate electrode 303 and drain electrode 302 can be efficiently reduced.

One of electron-supply assisting layer 401 closer to source electrode 301 or electron-supply assisting layer 401 closer to drain electrode 302 may not be in contact with gate electrode 303, and the other thereof may be in contact with gate electrode 303. For example, when the width of electron-supply assisting layer 401 closer to drain electrode 302 is within distance L stated above, electron-supply assisting layer 401 closer to source electrode 301 may be in contact with gate electrode 303. By adopting such a configuration, access resistance between source electrode 301 and gate electrode 303 can be decreased, and thus maximum drain current can be increased.

Alloy layer 402 is provided above electron-supply assisting layer 401 that is an n-type semiconductor layer. Specifically, alloy layer 402 is provided directly above electron-supply assisting layer 401, and is in contact with electron-supply assisting layer 401.

Alloy layer 402 is an Si based alloy layer containing Si. Alloy layer 402 results from elements included in first insulating layer 201 reacting with elements included in at least one of source electrode 301 or drain electrode 302. In this case, Si included in alloy layer 402 originates from Si contained in first insulating layer 201. In the present embodiment, since first insulating layer 201 is an SiN layer and source electrode 301 and drain electrode 302 are a laminated film of a Ti film and an Al film, alloy layer 402 is made of Ti, Al, Si, and N. Specifically, alloy layer 402 is a TiAlSiN alloy layer made of a TiAlSiN alloy and having a thickness of 1 nm. The thickness of alloy layer 402 is not limited to 1 nm, but may be at most 2 nm. By adopting such a configuration, the concentration of Si diffusing in electron supply layer 104 can be increased.

Note that the alloy included in alloy layer 402 is not limited to a TiAlSiN alloy, and an alloy of various combinations can be considered according to the type of an element included in first insulating layer 201 and the type of an element included in source electrode 301 and drain electrode 302. Specifically, alloy layer 402 may be made of an alloy containing Si and at least one element among Ti, Ta, Al, Au, Hf, Ru, and Cu.

Alloy layer 402 is not in contact with gate electrode 303, but is in contact with contact layer 212. In a plan view, alloy layer 402 is provided between contact layer 212 and first insulating layer 201. In the present embodiment, alloy layer 402 is in contact with not only contact layer 212, but also with first insulating layer 201.

In the present embodiment, alloy layer 402 is in contact with both source-side contact layer 212A and drain-side contact layer 212B. Note that alloy layer 402 may be in contact with just one of source-side contact layer 212A or drain-side contact layer 212B. Alloy layer 402 may be divided into a plurality of portions. In this case, among the plurality of portions, a portion of alloy layer 402 closer to source electrode 301 may be in contact with source-side contact layer 212A, and a portion of alloy layer 402 closer to drain electrode 302 may be in contact with drain-side contact layer 212B.

By configuring semiconductor device 1 having such a configuration, the electron concentration of two-dimensional electron gas layer 105 can be made different for a portion in which electron-supply assisting layer 401 and alloy layer 402 are present and a portion in which electron-supply assisting layer 401 and alloy layer 402 are not present. Specifically, two-dimensional electron gas layer 105 includes first two-dimensional electron gas layer 105A in a portion that is not located below electron-supply assisting layer 401 and alloy layer 402, and second two-dimensional electron gas layer 105B in a portion that is located below electron-supply assisting layer 401 and alloy layer 402, and the electron concentration of second two-dimensional electron gas layer 105B is higher than the electron concentration of first two-dimensional electron gas layer 105A. Note that contact layer 212 and second two-dimensional electron gas layer 105B are electrically connected by ohmic contact.

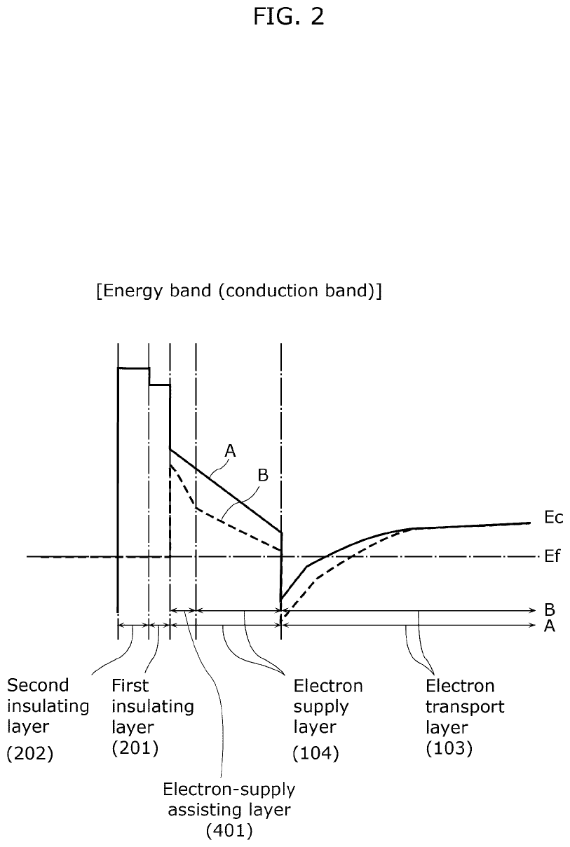

Here, the mechanism by which the electron concentration of second two-dimensional electron gas layer 105B is higher than the electron concentration of first two-dimensional electron gas layer 105A is described with reference to FIG. 2. FIG. 2 is a schematic diagram illustrating a conduction band of an energy band of semiconductor device 1 according to Embodiment 1.

In FIG. 2, solid line A represents a diagram of a portion corresponding to dash-dot line A in FIG. 1, and broken line B represents a diagram of a portion corresponding to dash-dot line B in FIG. 1. Stated differently, solid line A in FIG. 2 represents a diagram of a gate adjacent portion that is a portion adjacent to gate electrode 303 (that is, a portion in which electron-supply assisting layer 401 and alloy layer 402 are not provided), and names of corresponding layers are indicated by row (A) of lower two-directional arrows. Furthermore, broken line B in FIG. 2 represents a diagram of a contact adjacent portion that is a portion adjacent to contact layer 212 (that is, a portion in which electron-supply assisting layer 401 and alloy layer 402 are provided), and names of corresponding layers are indicated by row (B) of upper two-directional arrows. Note that the broken line above electron-supply assisting layer 401 (on the left thereof in the drawing) indicates that the Fermi level of drain electrode 302 that is metal coincides with the conduction band.

As described above, in semiconductor device 1 according to the present embodiment, electron-supply assisting layer 401 made of an n-type semiconductor is provided inside electron supply layer 104. Accordingly, in a portion in which electron supply layer 104 is provided, the potential of electron supply layer 104 relatively decreases, and thus the potential at the position of the interface between electron supply layer 104 and electron transport layer 103 decreases. As a result, the electron concentration of second two-dimensional electron gas layer 105B increases. Stated differently, the electron concentration of second two-dimensional electron gas layer 105B located below electron-supply assisting layer 401 is relatively higher than the electron concentration of first two-dimensional electron gas layer 105A not located below electron-supply assisting layer 401.

In this manner, since the electron concentration of second two-dimensional electron gas layer 105B is higher than the electron concentration of first two-dimensional electron gas layer 105A, a decrease in the electron concentration of a lateral-surface adjacent portion of each penetrating recessed portion 211 in electron supply layer 104 can be reduced. As a result, a decrease in maximum drain current can be reduced. In addition, since the electron concentration of the gate adjacent portion corresponding to first two-dimensional electron gas layer 105A is maintained, a leakage current between gate electrode 303 and drain electrode 302 can also be reduced. Thus, according to the configuration of semiconductor device 1 according to the present embodiment, a decrease in maximum drain current can be reduced and furthermore, leakage current between the gate and drain electrodes can be reduced. Not only current flowing through contact layer 212 but also current flowing through electron-supply assisting layer 401 and alloy layer 402 increase, and thus a decrease in maximum drain current can be further reduced.

Note that in semiconductor device 1 according to the present embodiment, the width of electron-supply assisting layer 401 may be at most 1 μm. By adopting such a configuration, leakage current between gate electrode 303 and drain electrode 302 can be efficiently reduced.

In semiconductor device 1 according to the present embodiment, under electron-supply assisting layer 401, a band gap of a portion of electron supply layer 104 closer to electron-supply assisting layer 401 may be smaller than a band gap of a portion of electron supply layer 104 closer to electron transport layer 103. Specifically, when electron supply layer 104 is made of AlGaN, the Al composition ratio of the portion of electron supply layer 104 closer to electron-supply assisting layer 401 may be lower than the Al composition ratio of the portion of electron supply layer 104 closer to electron transport layer 103. The higher the Al composition ratio of AlGaN is, the lower electron affinity of AlGaN is, and thus the height of a barrier when alloy layer 402 containing Si is brought into contact with electron-supply assisting layer 401 is low. Accordingly, by making the band gap of the portion of electron supply layer 104 closer to electron-supply assisting layer 401 smaller than the band gap of the portion of electron supply layer 104 closer to electron transport layer 103, an ohmic contact resistance can be reduced. Besides, variations in drain current can be decreased by decreasing the ohmic contact resistance.

In semiconductor device 1 according to the present embodiment, first insulating layer 201 and electron-supply assisting layer 401 may contain halogen such as fluorine (F) or chlorine (CI), but nevertheless the halogen concentrations of first insulating layer 201 and electron-supply assisting layer 401 may be both at most 1×10¹⁸ atoms/cm³. This is because halogen contained in the semiconductor layer and the insulating layer has high electronegativity, and thus has a fixed negative charge. Accordingly, since the halogen concentration of first insulating layer 201 is at most 1×10¹⁸ atoms/cm³, the fixed negative charge in first insulating layer 201 can be decreased. Accordingly, an increase in potential at an interface position between electron supply layer 104 and electron transport layer 103 can be reduced, and thus a decrease in electron concentration of second two-dimensional electron gas layer 105B due to halogen can be reduced.

In semiconductor device 1 according to the present embodiment, first insulating layer 201 may have a thickness greater than a thickness of alloy layer 402. By adopting such a configuration, leakage current between gate electrode 303 and drain electrode 302 can be further reduced.

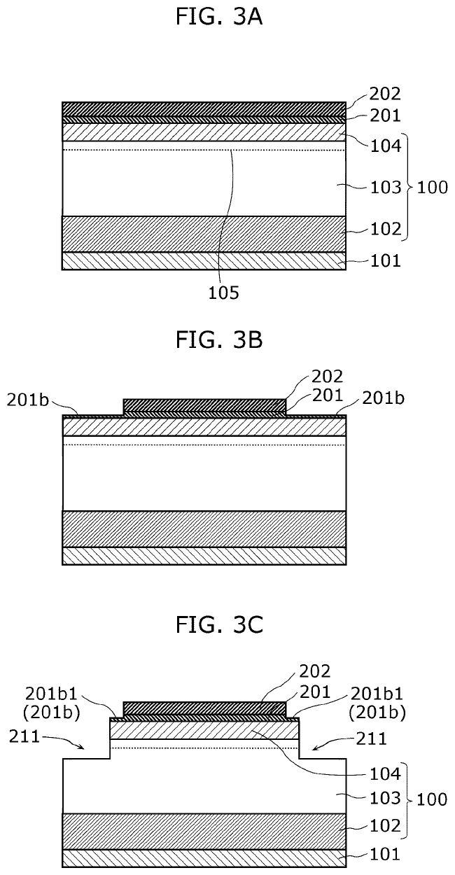

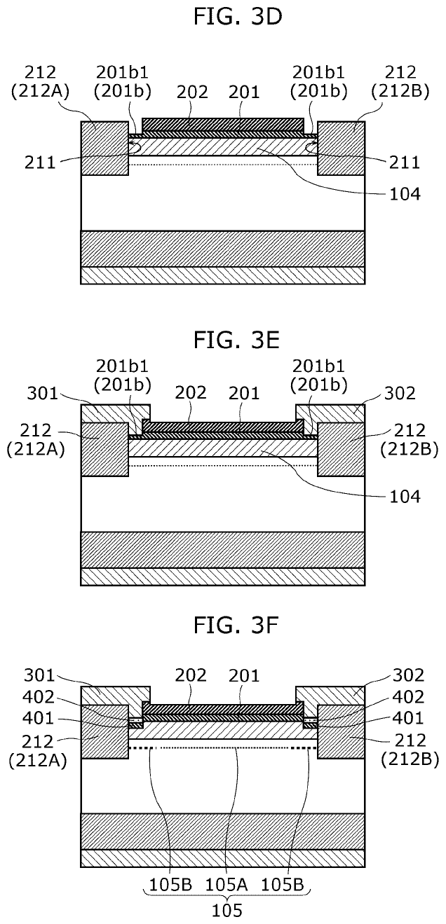

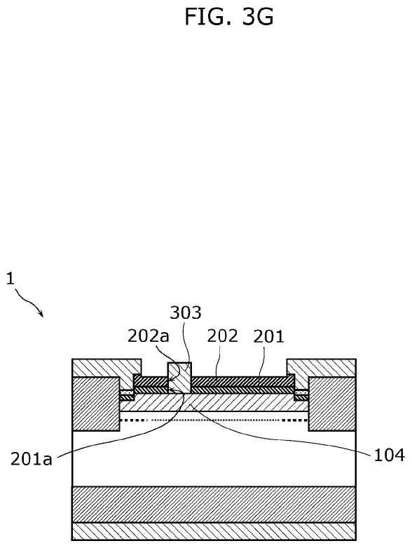

Next, a method for manufacturing semiconductor device 1 according to the present embodiment is described with reference to FIG. 3A to FIG. 3G. FIG. 3A to FIG. 3G are cross-sectional views illustrating processes of the method for manufacturing semiconductor device 1 according to Embodiment 1. FIG. 3A illustrates a process of forming semiconductor layered structure 100, first insulating layer 201, and second insulating layer 202. FIG. 3B illustrates a process of forming thin portion 201b in first insulating layer 201. FIG. 3C illustrates a process of forming penetrating recessed portions 211. FIG. 3D illustrates a process of forming contact layer 212. FIG. 3E illustrates a process of forming source electrode 301 and drain electrode 302. FIG. 3F illustrates a process of applying a heat treatment. FIG. 3G illustrates a process of forming gate electrode 303.

First, as illustrated in FIG. 3A, semiconductor layered structure 100 that includes buffer layer 102, electron transport layer 103, and electron supply layer 104 is formed above substrate 101 by using metal organic chemical vapor deposition (MOCVD) (a semiconductor layered structure forming process).

In the present embodiment, semiconductor layered structure 100 is formed above substrate 101 made of Si by sequentially epitaxially growing, in the +c plane direction (the <0001> direction), buffer layer 102 having a thickness of 2 μm and a structure of stacked AlN and AlGaN layers, electron transport layer 103 having a thickness of 200 nm and made of GaN, and electron supply layer 104 having a thickness of 20 nm and made of AlGaN having an Al composition ratio of 25%.

Next, first insulating layer 201 is formed, as an Si containing insulating layer, above semiconductor layered structure 100 (a first insulating layer forming process). Specifically, after forming semiconductor layered structure 100, first insulating layer 201 made of SiN and having a thickness of 2 nm is formed in the same semiconductor crystal growth device (MOCVD reactor). Thus, first insulating layer 201 is formed above electron supply layer 104 without exposing the inside of the reactor to the atmosphere. In this manner, oxygen is not maldistributed between electron supply layer 104 and first insulating layer 201 by forming first insulating layer 201 directly above electron supply layer 104 without exposure to the atmosphere. Next, second insulating layer 202 is formed above first insulating layer 201 (a second insulating layer forming process).

Specifically, after forming first insulating layer 201, substrate 101 above which semiconductor layered structure 100 and first insulating layer 201 are formed is moved to another device, and second insulating layer 202 made of SiO₂ and having a thickness of 50 nm is formed. In this structure, a highly concentrated two-dimensional electron gas is generated on the electron transport layer 103 side of the heterointerface between electron supply layer 104 and electron transport layer 103, and two-dimensional electron gas layer 105 is formed.

Note that as a deposition condition for forming first insulating layer 201 and second insulating layer 202, for example, the growth temperature is in a range of 900° C. to 1150° C., and the source gases are SiH₄ and NH₃. Use of halogen may be avoided in dry-cleaning the MOCVD reactor so as not to have halogen mixed, as an impurity, into first insulating layer 201. Even if halogen is used in dry cleaning, halogen can be removed from the MOCVD reactor by using N₂ or NH₃, for instance, after the dry cleaning.

Next, as illustrated in FIG. 3B, thin portions 201b are formed in first insulating layer 201 by thinning portions of first insulating layer 201 (a thin portion forming process).

Specifically, after applying a resist onto second insulating layer 202, the resist is patterned by the lithography method to form a mask (a resist mask) on a portion except regions of second insulating layer 202 in which contact layer 212, electron-supply assisting layer 401, and alloy layer 402 are to be formed. Thus, opening portions are formed in regions of the resist in which contact layer 212, electron-supply assisting layer 401, and alloy layer 402 are to be formed. Specifically, opening portions are formed in regions that include the regions in which source-side contact layer 212A and drain-side contact layer 212B are to be formed.

Next, by applying etching using the resist having the opening portions as a mask, portions of second insulating layer 202 are removed, and at the same time, portions of first insulating layer 201 are thinned. In this case, by applying dry etching and wet etching using the resist having the opening portions as a mask, second insulating layer 202 and first insulating layer 201 can be selectively removed. Thus, by applying dry etching and wet etching, portions of second insulating layer 202 are removed and also portions of first insulating layer 201 are thinned, for regions in which contact layer 212, electron-supply assisting layer 401, and alloy layer 402 are to be formed. Accordingly, as illustrated in FIG. 3B, thin portions 201b can be formed in first insulating layer 201 as a residual film by thinning portions of first insulating layer 201 (regions in which contact layer 212, electron-supply assisting layer 401, and alloy layer 402 are to be formed). After that, the mask (the resist) and a polymer generated in the dry etching are removed.

Note that when wet etching is applied to first insulating layer 201 and second insulating layer 202, second insulating layer 202 and first insulating layer 201 can be selectively removed by using DHF or BHF. When second insulating layer 202 made of SiO₂ is formed, only portions of first insulating layer 201 may be selectively removed by oxidizing the surface of first insulating layer 201.

Thin portions 201b (residual film) of first insulating layer 201 may have a thickness of at most 2 nm. In this case, thin portion 201b (residual film) of first insulating layer 201 may have a thickness that is at least half the thickness of first insulating layer 201 before being thinned (that is, half the thickness may be retained), but the thickness is not limited thereto. As an example, when the thickness of first insulating layer 201 before being thinned is 2 nm, thin portion 201b (the residual film) of first insulating layer 201 is 1.5 nm.

Next, as illustrated in FIG. 3C, penetrating recessed portions 211 are formed by removing end portions of thin portion 201b of first insulating layer 201 and portions of semiconductor layered structure 100 (a penetrating recessed portion forming process). Specifically, penetrating recessed portions 211 that penetrate through thin portions 201b of first insulating layer 201 and electron supply layer 104 and reach up to electron transport layer 103 are formed while retaining portions of thin portion 201b of first insulating layer 201 as insulating-layer remaining portions 201b1.

In this case, first, a resist is applied onto second insulating layer 202 and a portion of each thin portion 201b of first insulating layer 201, after which the resist is patterned by the lithography method, so that a mask (resist mask) is formed over a region other than the regions in which penetrating recessed portions 211 are to be formed. Thus, opening portions are formed in the regions of the resist in which penetrating recessed portions 211 are to be formed. Specifically, the resist has opening portions in the regions in which source-side contact layer 212A and drain-side contact layer 212B are to be formed.

Next, dry etching is performed using the resist having such opening portions as a mask, to form penetrating recessed portions 211 that penetrate through end portions of thin portions 201b of first insulating layer 201 and electron supply layer 104 and reach up to electron transport layer 103, while retaining portions of thin portions 201b of first insulating layer 201 as insulating-layer remaining portions 201b1. Specifically, as illustrated in FIG. 3C, two penetrating recessed portions 211 are formed in correspondence with the regions in which source-side contact layer 212A and drain-side contact layer 212B are to be formed. Portions of electron transport layer 103 are exposed by forming penetrating recessed portions 211. After that, the mask (the resist) and a polymer generated in the dry etching are removed.

Note that penetrating recessed portions 211 are formed by dry etching in the present embodiment, but the method is not limited to this. Specifically, penetrating recessed portions 211 may be formed by wet etching.

After forming penetrating recessed portions 211 by thinning first insulating layer 201 and dry etching, the lateral surfaces of electron supply layer 104 may be selectively subjected to wet etching by using SPM, APM, or KOH. Accordingly, the lateral surfaces of penetrating recessed portions 211 can be made slanting. Specifically, the lateral surfaces of penetrating recessed portions 211 can be each formed into a slanting surface having an elevation angle of at most 5 degrees in a direction from the center of the bottom surface of penetrating recessed portion 211 to the lateral portion thereof.

Next, as illustrated in FIG. 3D, contact layer 212 is embedded and formed in penetrating recessed portions 211 (a contact layer forming process).

Specifically, n⁺-GaN is grown by using MOCVD to fill two penetrating recessed portions 211 by using second insulating layer 202 and insulating-layer remaining portions 201b1 of first insulating layer 201 as a mask. Accordingly, contact layer 212 made of n⁺-GaN can be selectively embedded and formed in two penetrating recessed portions 211. Note that contact layer 212 embedded in one of two penetrating recessed portions 211 is source-side contact layer 212A, and contact layer 212 embedded in the other of two penetrating recessed portions 211 is drain-side contact layer 212B.

In the present embodiment, Si is doped as an n-type impurity and n⁺-GaN is grown to have a thickness of 100 nm, to form contact layer 212. The Si doping concentration of contact layer 212 is 2×10¹⁹/cm³, for example.

Note that contact layer 212 may be formed not by being regrown but by sputtering, or may be formed by ion implantation and plasma treatment, for instance, without forming penetrating recessed portions 211.

Next, as illustrated in FIG. 3E, source electrode 301 and drain electrode 302 are formed over insulating-layer remaining portions 201b1 of first insulating layer 201 and contact layer 212 (a source electrode/drain electrode forming process).

Specifically, after forming a layered film by depositing a Ti film having a thickness of 30 nm and an Al film having a thickness of 200 nm in this order by vapor deposition or sputtering, an unnecessary portion of the layered film is removed by the lift-off method, so that source electrode 301 and drain electrode 302 made of the layered film of the Ti film and the Al film and having predetermined shapes are formed above contact layer 212. In the present embodiment, source electrode 301 is formed above source-side contact layer 212A, and drain electrode 302 is formed above drain-side contact layer 212B. After that, the resist mask and the polymer are removed.

Note that in the present embodiment, source electrode 301 and drain electrode 302 are formed by vapor deposition and the lift-off method, but are not limited to be formed thereby. For example, after a layered film is formed by depositing a Ti film and an Al film in this order by sputtering, source electrode 301 and drain electrode 302 in predetermined shapes may be formed by patterning the layered film by using the lithography method and the dry etching method.

Next, as illustrated in FIG. 3F, electron-supply assisting layer 401 and alloy layer 402 are formed in insulating-layer remaining portions 201b1 of first insulating layer 201 and electron supply layer 104 by applying a heat treatment (a heat treatment process).

The temperature for this heat treatment is in a range of 400° C. to 600° C., and may be in a range of 500° C. to 550° C. The heat treatment may be performed under an atmosphere that does not contain oxygen. In the present embodiment, the heat treatment is applied at a temperature of 540° C. under N₂ atmosphere.

By applying a heat treatment in this manner, elements of insulating-layer remaining portions 201b1 of first insulating layer 201 and electron supply layer 104 and elements of source electrode 301 and drain electrode 302 are mutually diffused and alloyed by the heat to form electron-supply assisting layer 401 and alloy layer 402.

Specifically, in the present embodiment, first insulating layer 201 is an insulating layer containing Si and electron supply layer 104 is an AlGaN layer, and thus in upper layer portions of electron supply layer 104 in contact with insulating-layer remaining portions 201b1 of first insulating layer 201, nitrogen vacancies are formed by the diffusion of Si contained in first insulating layer 201 so that the upper layer portions are made n-type, and an n-type AlGaN layer is formed as electron-supply assisting layer 401. Thus, electron-supply assisting layer 401 that is an n-type semiconductor layer is formed.

In addition, in the present embodiment, source electrode 301 and drain electrode 302 contain Ti, and thus the upper layer portions of electron supply layer 104 are made n-type by forming nitrogen vacancies by the diffusion of Ti. Thus, in the present embodiment, the upper layer portions of electron supply layer 104 are made n-type by the diffusion of Si and the diffusion of Ti by a heat treatment, so that electron-supply assisting layer 401 that is an n-type semiconductor layer is formed.

In this manner, the upper layer portions of electron supply layer 104 are made n-type so that electron-supply assisting layer 401 that is an n-type semiconductor layer is formed, and thus second two-dimensional electron gas layer 105B having a higher electron concentration than that of first two-dimensional electron gas layer 105A is generated. As a result, second two-dimensional electron gas layer 105B, source electrode 301, and drain electrode 302 are electrically connected by ohmic contact.

Note that insulating-layer remaining portion 201b1 that is a portion of each thin portion 201b of first insulating layer 201 may be thinner in order that Si in first insulating layer 201 is readily diffused to electron supply layer 104 by a heat treatment. In this case, as stated above, the thickness of thin portion 201b of first insulating layer 201 may be at most 2 nm. By adopting such a configuration, the content of Si in the upper layer portions of electron supply layer 104 can be increased, and the upper layer portions of electron supply layer 104 can be further made n-type.

Next, as illustrated in FIG. 3G, a portion of first insulating layer 201 that is a portion of first insulating layer 201 separated from source electrode 301 and drain electrode 302 is removed to form gate electrode 303 (a gate electrode forming process). In the present embodiment, since second insulating layer 202 is formed above first insulating layer 201, a portion of first insulating layer 201 and a portion of second insulating layer 202 that are separated from source electrode 301 and drain electrode 302 are removed to form gate electrode 303.

Specifically, after applying a resist above second insulating layer 202, a mask (a resist mask) is formed in a region other than the region in which gate electrode 303 is to be formed (a region in which a gate-electrode is scheduled to be formed) by the lithography method. Subsequently, second insulating layer 202 and first insulating layer 201 are selectively removed by using the dry etching method to form opening portion 201a in first insulating layer 201 so that electron supply layer 104 is exposed and to also form opening portion 202a of second insulating layer 202. Next, the mask (the resist mask) and a polymer generated in the dry etching are removed. After that, gate electrode 303 is formed in opening portions 201a and 202a. Specifically, after forming a layered film in which a TiN film having a thickness of 50 nm and an Al film having a thickness of 450 nm are deposited in this order by the sputtering method, the layered film is patterned by using the lithography method and the dry etching method to form gate electrode 303 in a predetermined shape illustrated in FIG. 3F. After that, the mask and a polymer generated in the dry etching are removed.

In this manner, semiconductor device 1 having the structure illustrated in FIG. 1 is completed through the series of processes in FIG. 3A to FIG. 3G.

### Embodiment 2

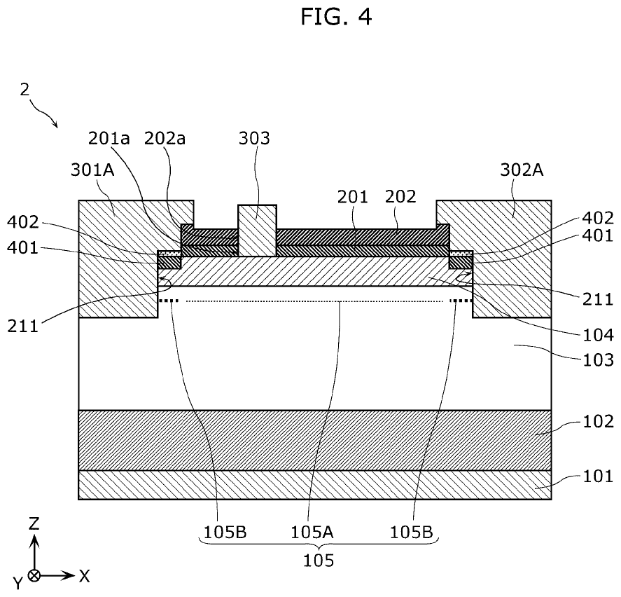

Next, semiconductor device 2 according to Embodiment 2 is described with reference to FIG. 4. FIG. 4 is a cross-sectional view illustrating a configuration of semiconductor device 2 according to Embodiment 2. Note that in the following, differences from Embodiment 1 are mainly described, and description of common points is omitted or simplified.

Semiconductor device 2 according to the present embodiment is different from semiconductor device 1 according to Embodiment 1 above in the configurations of source electrode 301A and drain electrode 302A. Specifically, source electrode 301A and drain electrode 302A in the present embodiment result from making source electrode 301, drain electrode 302, and contact layer 212 in semiconductor device 1 according to Embodiment 1 above using the same material and integrating source electrode 301 and drain electrode 302 with contact layer 212.

More specifically, source electrode 301A in the present embodiment results from making source electrode 301 and source-side contact layer 212A in Embodiment 1 above using the same material and integrating source electrode 301 with source-side contact layer 212A. Furthermore, drain electrode 302A in the present embodiment results from making drain electrode 302 and drain-side contact layer 212B in Embodiment 1 above using the same material and integrating drain electrode 302 with drain-side contact layer 212B. Thus, semiconductor device 2 according to the present embodiment does not include a contact layer made of a semiconductor material.

In the present embodiment, source electrode 301A and drain electrode 302A are provided being embedded in penetrating recessed portions 211. Source electrode 301A and drain electrode 302A are each provided covering alloy layer 402 and a portion of second insulating layer 202. Source electrode 301A and drain electrode 302A are configured of, for example, a multi-layer electrode film having a layered structure in which a Ti film having a thickness of 30 nm and an Al film having a thickness of 200 nm are stacked in this order, but are not limited to these. Source electrode 301A and drain electrode 302A do not contain Au, but the configuration is not limited thereto. Source electrode 301A and drain electrode 302A may be made using at least one of Ti, Ta, Al, Hf, Ru, or Cu.

Source electrode 301A and drain electrode 302A having such a configuration are electrically connected to second two-dimensional electron gas layer 105B by ohmic contact.

Semiconductor device 2 according to the present embodiment can also yield effects similar to those yielded in Embodiment 1 above. Specifically, also in the present embodiment, electron-supply assisting layer 401 that is an n-type semiconductor layer and alloy layer 402 are provided, and thus the electron concentration of second two-dimensional electron gas layer 105B is higher than the electron concentration of first two-dimensional electron gas layer 105A. Accordingly, a decrease in electron concentration of portions of electron supply layer 104 adjacent to the lateral-surfaces of penetrating recessed portions 211 can be reduced, and a decrease in maximum drain current can be reduced.

Furthermore, in semiconductor device 2 according to the present embodiment, source electrode 301A and drain electrode 302A function also as a contact layer, so that a contact layer made of a semiconductor material is not provided. Accordingly, a process of forming a contact layer can be omitted. In semiconductor device 2 according to the present embodiment, source electrode 301A and drain electrode 302A do not contain Au, and thus a manufacturing const can be reduced.

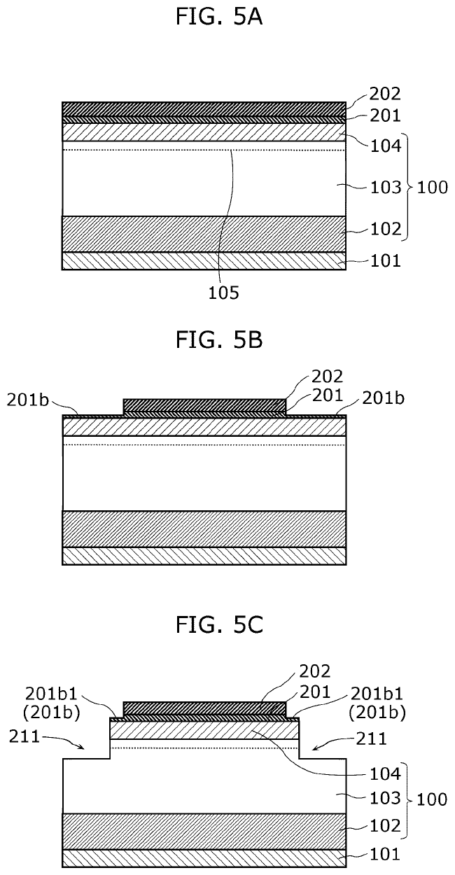

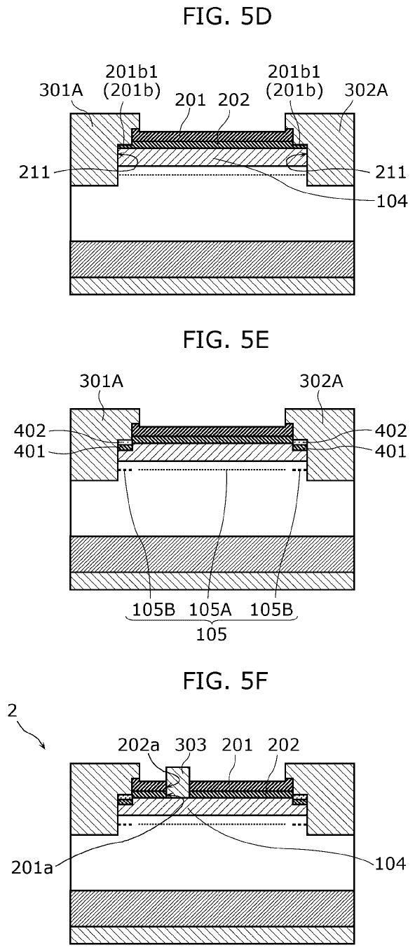

Next, a method for manufacturing semiconductor device 2 according to the present embodiment is described with reference to FIG. 5A to FIG. 5F. FIG. 5A to FIG. 5F are cross-sectional views illustrating processes of the method for manufacturing semiconductor device 2 according to Embodiment 2. FIG. 5A illustrates a process of forming semiconductor layered structure 100, first insulating layer 201, and second insulating layer 202. FIG. 5B illustrates a process of forming thin portions 201b in first insulating layer 201. FIG. 5C illustrates a process of forming penetrating recessed portions 211. FIG. 5D illustrates a process of forming source electrode 301A and drain electrode 302A. FIG. 5E illustrates a process of applying a heat treatment. FIG. 5F illustrates a process of forming gate electrode 303.

First, as illustrated in FIG. 5A, semiconductor layered structure 100 that includes buffer layer 102, electron transport layer 103, and electron supply layer 104 is formed above substrate 101 by using metal organic chemical vapor deposition (MOCVD) (a semiconductor layered structure forming process). This process is the same as the process in FIG. 3A in Embodiment 1 above.

Next, as illustrated in FIG. 5B, thin portions 201b are formed in first insulating layer 201 by thinning portions of first insulating layer 201 (a thin portion forming process). This process is the same as the process in FIG. 3B in Embodiment 1 above.

Next, as illustrated in FIG. 5C, penetrating recessed portions 211 are formed by removing end portions of thin portions 201b of first insulating layer 201 and portions of semiconductor layered structure 100 (a penetrating recessed portion forming process). Specifically, penetrating recessed portions 211 that penetrate through thin portions 201b of first insulating layer 201 and electron supply layer 104 and reach up to electron transport layer 103 are formed while retaining portions of thin portions 201b of first insulating layer 201 as insulating-layer remaining portions 201b1. This process is the same as the process in FIG. 3C in Embodiment 1 above.

Next, as illustrated in FIG. 5D, source electrode 301A and drain electrode 302A are embedded and formed in penetrating recessed portions 211 (a source electrode/drain electrode forming process). Specifically, source electrode 301A and drain electrode 302A are formed over insulating-layer remaining portions 201b1 of first insulating layer 201 and penetrating recessed portions 211.

In the present embodiment, by using second insulating layer 202 and first insulating layer 201 as a mask, a Ti film and an Al film are deposited in this order by sputtering to be embedded in penetrating recessed portions 211 so that a layered film is formed, and thereafter a mask is formed in regions in which source electrode 301A and drain electrode 302A are to be formed by the lithography method. The regions in which the mask is formed are regions over penetrating portions 211, insulating-layer remaining portions 201b1 of first insulating layer 201, and second insulating layer 202 in a plan view. After that, the Al film and the Ti film in a region other than the regions in which the mask is formed are removed by the dry etching method, to form source electrode 301A and drain electrode 302A over insulating-layer remaining portions 201b1 of first insulating layer 201 and penetrating recessed portions 211. After that, the mask and a polymer are removed.

Next, as illustrated in FIG. 5E, electron-supply assisting layer 401 and alloy layer 402 are formed in insulating-layer remaining portions 201b1 of first insulating layer 201 and electron supply layer 104 by applying a heat treatment (a heat treatment process). This process is the same as the process in FIG. 3F in Embodiment 1 above. Thus, by applying a heat treatment, elements of insulating-layer remaining portions 201b1 of first insulating layer 201 and electron supply layer 104 and elements of source electrode 301A and drain electrode 302A are mutually diffused and alloyed by the heat to form electron-supply assisting layer 401 and alloy layer 402.

Next, as illustrated in FIG. 5F, a portion of first insulating layer 201 that is a portion of first insulating layer 201 separated from source electrode 301A and drain electrode 302A is removed to form gate electrode 303 (a gate electrode forming process). In the present embodiment, since second insulating layer 202 is formed above first insulating layer 201, a portion of first insulating layer 201 and a portion of second insulating layer 202 that are separated from source electrode 301A and drain electrode 302A are removed to form gate electrode 303. This process is the same as the process in FIG. 3G in Embodiment 1 above.

In this manner, semiconductor device 2 having the structure illustrated in FIG. 4 is completed through the series of processes in FIG. 5A to FIG. 5F.

### Variations

The semiconductor devices according to the present disclosure have been described in the above, based on Embodiments 1 and 2, but the present disclosure is not limited to Embodiment 1 or 2.

For example, electron transport layer 103 and electron supply layer 104 are made of group III nitride semiconductors in Embodiments 1 and 2 above, but the material is not limited thereto. Specifically, electron transport layer 103 and electron supply layer 104 may be made of other semiconductor materials such as a group III arsenide semiconductor.

The present disclosure also encompasses embodiments as a result of adding, to the embodiments, various modifications that may be conceived by those skilled in the art, and embodiments obtained by combining elements and functions in the embodiments without departing from the purport of the present disclosure. The present disclose also encompasses any combination of two or more claims within a technically consistent range among the claims stated in the claim section of the present application as originally filed. For example, when the dependent claims recited in the claim section of the present application as originally filed are made multiple dependent claims or multiple dependent claims that are dependent from multiple dependent claims, the present disclose also encompasses all the combinations of the claims in the multiple dependent claims or the multiple dependent claims that are dependent from multiple dependent claims.

Although only some exemplary embodiments of the present disclosure have been described in detail above, those skilled in the art will readily appreciate that many modifications are possible in the exemplary embodiments without materially departing from the novel teachings and advantages of the present disclosure. Accordingly, all such modifications are intended to be included within the scope of the present disclosure.

### INDUSTRIAL APPLICABILITY

The technology of the present disclosure can be used as a semiconductor device such as a switching transistor used in a communication device and an inverter for which a high-speed operation is expected and a power supply circuit. Among the above, the technology of the present disclosure is useful in particular to a high frequency power device having a great influence on heat generated due to an ohmic contact resistance.

1. A semiconductor device comprising:
an electron transport layer;
an electron supply layer provided above the electron transport layer and having a band gap greater than a band gap of the electron transport layer;
a gate electrode provided above the electron supply layer;
a source-side contact layer and a drain-side contact layer that are embedded in recessed portions that penetrate through the electron supply layer, at positions between which the gate electrode is provided;
an n-type semiconductor layer provided in contact with the electron supply layer and at least one of the source-side contact layer or the drain-side contact layer and not in contact with the gate electrode, the n-type semiconductor layer being made of an n-type semiconductor containing Si;
an alloy layer provided above the n-type semiconductor layer, containing Si, and having a thickness of at most 2 nm;
an insulating layer provided above a portion of the electron supply layer in which the gate electrode is not provided, in contact with the gate electrode, and not in contact with at least one of the source-side contact layer or the drain-side contact layer; and
at least one of a source electrode or a drain electrode provided above the alloy layer and at least one of the source-side contact layer or the drain-side contact layer.

2. The semiconductor device according to claim 1,
wherein the n-type semiconductor layer has a thickness of at most 2 nm.

3. The semiconductor device according to claim 1,
wherein in a cross-sectional view, the n-type semiconductor layer has a width of at most 1 μm.

4. The semiconductor device according to claim 1,
wherein under the n-type semiconductor layer, a band gap of a portion of the electron supply layer closer to the n-type semiconductor layer is smaller than a band gap of a portion of the electron supply layer closer to the electron transport layer.

5. The semiconductor device according to claim 1,
wherein the source electrode and the source-side contact layer are made of a same material and do not contain Au, and
the drain electrode and the drain-side contact layer are made of a same material and do not contain Au.

6. The semiconductor device according to claim 1,
wherein the insulating layer has a halogen concentration of at most 1×10¹⁸ atoms/cm³.

7. The semiconductor device according to claim 1,
wherein the insulating layer has a thickness greater than a thickness of the alloy layer.

8. The semiconductor device according to claim 7,
wherein the insulating layer has a thickness of at least 2 nm and at most 30 nm.

9. The semiconductor device according to claim 1,
wherein oxygen is not maldistributed between the insulating layer and the electron supply layer.

10. The semiconductor device according to claim 1,
wherein the electron transport layer and the electron supply layer are each made of a group III nitride semiconductor.

11. A method for manufacturing a semiconductor device, the method comprising:
forming an electron supply layer above an electron transport layer, the electron supply layer having a band gap greater than a band gap of the electron transport layer;
forming an insulating layer containing Si above the electron supply layer without exposure to atmosphere;
forming a thin portion in the insulating layer by thinning a portion of the insulating layer;
forming a penetrating recessed portion that penetrates through the thin portion of the insulating layer and the electron supply layer and reaches up to the electron transport layer while retaining a portion of the thin portion as an insulating-layer remaining portion;
embedding a contact layer in the penetrating recessed portion;
forming at least one of a source electrode or a drain electrode over the insulating-layer remaining portion and the contact layer;
forming an alloy layer and an electron-supply assisting layer in the insulating-layer remaining portion and the electron supply layer by applying a heat treatment; and
removing a portion of the insulating layer that is separated from the at least one of the source electrode or the drain electrode to form a gate electrode.

12. A method for manufacturing a semiconductor device, the method comprising:
forming an electron supply layer above an electron transport layer, the electron supply layer having a band gap greater than a band gap of the electron transport layer;
forming an insulating layer containing Si above the electron supply layer without exposure to atmosphere;
forming a thin portion in the insulating layer by thinning a portion of the insulating layer;
forming a penetrating recessed portion that penetrates through the thin portion of the insulating layer and the electron supply layer and reaches up to the electron transport layer while retaining a portion of the thin portion as an insulating-layer remaining portion;
forming at least one of a source electrode or a drain electrode over the insulating-layer remaining portion and the penetrating recessed portion;
forming an alloy layer and an electron-supply assisting layer in the insulating-layer remaining portion and the electron supply layer by applying a heat treatment; and
removing a portion of the insulating layer that is separated from the at least one of the source electrode or the drain electrode to form a gate electrode.

13. The method according to claim 11,
wherein the insulating layer is made of SiN.

14. The method according to claim 13,
wherein oxygen is not maldistributed between the insulating layer and the electron supply layer.

15. The method according to claim 11,
wherein in the forming of the thin portion in the insulating layer, the thin portion has a thickness of at most 2 nm.

16. The method according to claim 11,
wherein the electron transport layer and the electron supply layer are each made of a group III nitride semiconductor.

17. The method according to claim 12,
wherein the insulating layer is made of SiN.

18. The method according to claim 17,
wherein oxygen is not maldistributed between the insulating layer and the electron supply layer.

19. The method according to claim 12,
wherein in the forming of the thin portion in the insulating layer, the thin portion has a thickness of at most 2 nm.

20. The method according to claim 12,
wherein the electron transport layer and the electron supply layer are each made of a group III nitride semiconductor.
